(19) United States
(12) Patent Application Publication
(10) Pub. No.: US 2016/0079218 A1
(43) Pub. Date: Mar. 17, 2016

(54) ELECTROSTATIC PROTECTION DEVICE AND LIGHT-EMITTING MODULE

(71) Applicant: MURATA MANUFACTURING CO., LTD., Kyoto (JP)

(72) Inventors: Kiminori WATANABE, Tokyo (JP); Seiichi SATO, Tokyo (JP); Toshiya WATANABE, Tokyo (JP); Tadayuki OKAWA, Nagaokakyo-shi (JP); Kiyoto ARAKI, Nagaokakyo-shi (JP); Teiji YAMAMOTO, Nagaokakyo-shi (JP)

(73) Assignee: MURATA MANUFACTURING CO., LTD., Kyoto (JP)

(21) Appl. No.: 14/936,256

(22) Filed: Nov. 9, 2015

Related U.S. Application Data
(63) Continuation of application No. PCT/JP2014/058720, filed on Mar. 27, 2014.

(30) Foreign Application Priority Data
May 8, 2013 (JP) 2013-098349

(51) Int. Cl. H01L 25/16; H01L 23/58; H01L 23/48; H01L 33/62; H01L 29/866; H01L 23/60

(52) U.S. Cl. CPC H01L 25/167; H01L 29/866; H01L 23/60; H01L 23/481; H01L 33/62; H01L 23/585

(57) ABSTRACT

An electrostatic protection device includes a base member formed of a high-resistance semiconductor material. External connecting lands are formed on a first principal surface of the base member along a first direction with a space therebetween. A diode section is formed in the first principal surface of the base member through a semiconductor forming process. The diode section is formed between formation regions of the external connecting lands along the first direction. A high concentration region is a region that has the same polarity as the base member and contains larger amounts of impurities than the base member. The high concentration region is formed in a ring shape enclosing the diode section in a plan view of the base member.

### CROSS REFERENCE TO RELATED APPLICATION

This application claims benefit of priority to Japanese Patent Application No. 2013-098349 filed May 8, 2013, and to International Patent Application No. PCT/JP2014/058720 filed Mar. 27, 2014, the entire content of which is incorporated herein by reference.

### TECHNICAL FIELD

The present invention relates to electrostatic protection devices having an ESD protection function and light-emitting modules provided with light-emitting devices such as LEDs or the like.

### BACKGROUND

Various types of light-emitting modules having LEDs as light-emitting sources have been developed. In general, a light-emitting module using such LED is equipped with an electrostatic protection device so as to prevent electrostatic breakdown of the LED.

For example, in Japanese Unexamined Patent Application Publication No. 2007-36238, a light-emitting module having an electrostatic protection function is formed with a structure in which an LED device is mounted on a front surface of a base member and a Zener diode is mounted on a rear surface of the base member. However, it is difficult for this structure to lower the height of the light-emitting module. As such, as a method for lowering the height of the light-emitting module having the electrostatic protection function, a configuration in which a Zener diode serving as an electrostatic protection device is embedded in the base member can be thought of.

To be more specific, a base member whose planar area is substantially the same as that of the LED device is prepared. A first external connecting land and a second external connecting land are formed on a rear surface of the base member, and a first mounting land and a second mounting land are formed on a front surface of the base member. The first external connecting land and the first mounting land are electrically connected to each other, and the second external connecting land and the second mounting land are also electrically connected to each other. External connecting terminals of the LED device are mounted on the first mounting land and the second mounting land, respectively.

Inside the base member, a Zener diode that connects the first external connecting land to the second external connecting land is formed through a semiconductor forming process. For example, a pn junction structure is formed in a region ranging from the rear surface of the base member to a predetermined depth thereof by a doping method from the rear surface side of the base member.

In the structure discussed above, as a structure in which the first external connecting land and the first mounting land are electrically connected to each other and the second external connecting land and the second mounting land are electrically connected to each other, such a structure can be considered that the base member is formed of a low-resistance semiconductor. However, in the case where a low-resistance semiconductor is used as a conductor, an insulation gap to insulate the first external connecting land and first mounting land from the second external connecting land and second mounting land needs to be formed in the base member, but it is difficult to form such an insulation gap.

As such, a structure in which the base member is formed of a high-resistance semiconductor, and a conductive via for electrically connecting the first external connecting land and the first mounting land as well as a conductive via for electrically connecting the second external connecting land and the second mounting land are provided, can be considered.

### SUMMARY

### Technical Problem

However, even in the case where the base member is formed of a high-resistance semiconductor, a leak current flows between the first external connecting land and the second external connecting land in some instances. In other words, there is a case where the first external connecting land and the second external connecting land are in a state of not being insulated from each other.

Accordingly, an object of the present disclosure is to provide an electrostatic protection device and a light-emitting module capable of more surely suppressing the leak current in a structure using a base member formed of a high-resistance semiconductor.

### Solution to Problem

An electrostatic protection device of the present disclosure includes a base member formed of a semiconductor material and a diode section. The diode section is formed on a first principal surface side of the base member through a semiconductor forming process.

In addition, the base member has such resistivity that causes the formation of a conductivity type inversion layer in the base member by applying a voltage from the exterior, carrying out heat treatment, and so on, and includes a high concentration region configured as follows. That is, the high concentration region is formed in a shape extending from the first principal surface to the interior of the base member so as to enclose the diode section in a plan view of the base member when seen from the first principal surface side, is the same conductivity type as the base member, and has a higher impurity concentration than the base member.

In this configuration, the diode section is isolated by the high concentration region. Accordingly, even if a current flows in the conductivity type inversion layer due to solder being attached to one end surface of the base member or the like, the current will not reach the diode section because the current is blocked by the high concentration region. This makes it possible to suppress the generation of a leak current.

It is preferable for the electrostatic protection device of the present disclosure to be configured as follows. That is, the high concentration region includes an enclosure portion enclosing the diode section and at least one of a first extension portion and a second extension portion. The first extension portion is formed in a shape connected to the enclosure portion and extending to both ends of the first principal surface opposing each other. The second extension portion is formed in a shape connected to the enclosure portion and extending to respective corners of the first principal surface.

In this configuration, even if a current flows in the conductivity type inversion layer due to solder being attached to both end surfaces of the base member in a direction orthogonal to the direction in which the first extension portion extends, the current is blocked by the high concentration region, thereby making it possible to suppress the generation of a leak current. In other words, the generation of a leak current can be more surely suppressed.

Further, in the electrostatic protection device of the present disclosure, the high concentration region is formed in a ring shape embracing a first external connecting land and a second external connecting land in a plan view of the first principal surface.

In this configuration, even if such a voltage is applied to the base member or such heat treatment is carried out thereon that can cause a conductivity type inversion layer to be formed, the conductivity type inversion layer will not be generated on a surface of the high concentration region. This makes it possible to more surely suppress the generation of a leak current.

It is preferable in the electrostatic protection device of the present disclosure that a width of the high concentration region be wider as the resistivity of the base member is higher.

In the above configuration, because the width of the high concentration region is determined in accordance with the resistivity of the base member, the generation of a leak current can be suppressed with certainty.

The electrostatic protection device of the present disclosure includes a first external connecting land and a second external connecting land. These lands are formed on the first principal surface of the base member with a predetermined space therebetween along a first direction of the first principal surface. Further, the diode section is formed between the first external connecting land and the second external connecting land on the first principal surface side of the base member. The diode section connects the first external connecting land and the second external connecting land.

In this configuration, the conductivity type inversion layer between the first external connecting land and the diode section is isolated by the high concentration region. Likewise, the conductivity type inversion layer between the second external connecting land and the diode section is also isolated by the high concentration region. Accordingly, even if a current flows in the conductivity type inversion layer due to the solder being attached to the one end surface of the base member or the like, the current does not reach the diode section because the current is blocked by the high concentration region. This makes it possible to suppress the generation of a leak current.

It is preferable for the electrostatic protection device of the present disclosure to be configured as follows. That is, the electrostatic protection device further includes a first mounting land and a second mounting land, and a first via conductor and a second via conductor. The first and second mounting lands are formed on a second principal surface of the base member opposing the first principal surface thereof. The first via conductor connects the first external connecting land and the first mounting land. The second via conductor connects the second external connecting land and the second mounting land.

In the above configuration, an electronic component to be protected against electrostatic charge can be mounted on the second principal surface of the electrostatic protection device.

A light-emitting module of the present disclosure includes the above-mentioned electrostatic protection device and a light-emitting device. A first external terminal of the light-emitting device is mounted on the first mounting land, and a second external terminal thereof is mounted on the second mounting land.

In this configuration, the light-emitting device to be protected against electrostatic charge and the electrostatic protection device are integrally formed, whereby a small and thin light-emitting module can be realized.

### Advantageous Effects of Disclosure

According to the present disclosure, in the structure using a base member formed of a high-resistance semiconductor, a leak current can be more surely suppressed by blocking a current path produced in the conductivity type inversion layer.

### BRIEF DESCRIPTION OF DRAWINGS

FIGS. 1(A)-1(D) include drawings illustrating a configuration of an electrostatic protection device according to a first embodiment of the present disclosure.

FIGS. 2(A)-2(C) include drawings for explaining effects of the electrostatic protection device according to the first embodiment of the present disclosure. 3(A) and 3(B) illustrate experiment results for explaining leak current suppression effects of the electrostatic protection device according to the first embodiment of the present disclosure.

FIGS. 4(A)-4(F) include drawings illustrating a manufacturing process of the electrostatic protection device according to the first embodiment of the present disclosure.

FIG. 5 is a cross-sectional side view illustrating a configuration of a light-emitting module according to the first embodiment of the present disclosure.

FIGS. 6(A)-6(E) include drawings illustrating a manufacturing process of the light-emitting module according to the first embodiment of the present disclosure.

FIG. 7 is a configuration diagram of an electrostatic protection device according to a second embodiment of the present disclosure.

FIGS. 8(A) and 8(B) include drawings for explaining effects of the electrostatic protection device according to the second embodiment of the present disclosure.

FIG. 9 is a configuration diagram of an electrostatic protection device according to a third embodiment of the present disclosure.

FIG. 10 is a diagram for explaining effects of the electrostatic protection device according to the third embodiment of the present disclosure.

FIG. 11 is a configuration diagram of an electrostatic protection device according to a fourth embodiment of the present disclosure.

### DETAILED DESCRIPTION

An electrostatic protection device and a light-emitting device according to a first embodiment of the present disclosure will be described with reference to the drawings.

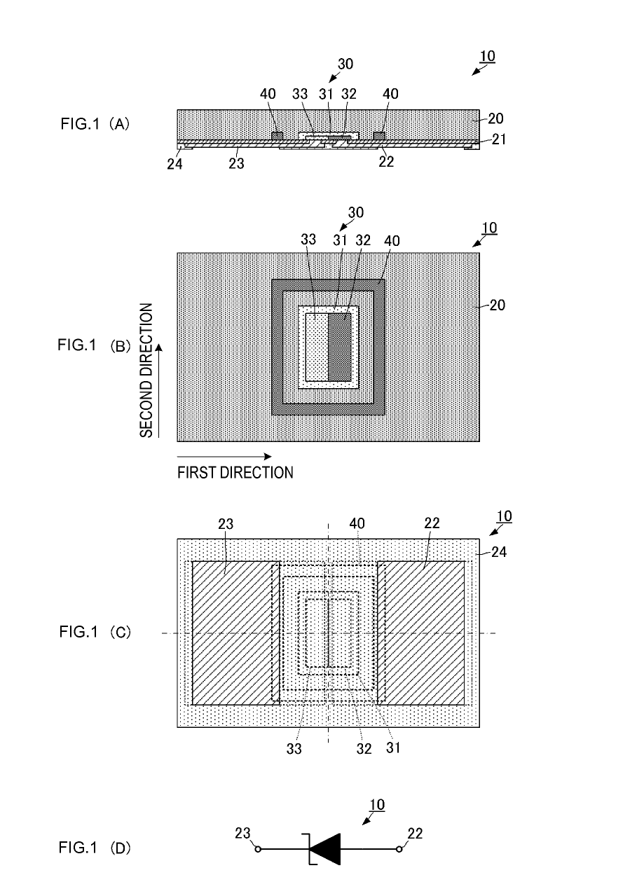

FIGS. 1(A)-1(D) include drawings illustrating a configuration of an electrostatic protection device according to the first embodiment of the present disclosure. FIG. 1(A) is a cross-sectional side view of the electrostatic protection device, FIG. 1(B) is a plan view of a base member on a first principal surface side, FIG. 1(C) is a plan view of the electrostatic protection device on the first principal surface side, and FIG. 1(D) is an equivalent circuit diagram.

An electrostatic protection device 10 includes a base member 20 formed in a rectangular plate shape, an insulation layer 21, external connecting lands 22 and 23, a protection layer 24, a diode section 30, and a high concentration region 40.

The base member 20 is formed of a high-resistance semiconductor. Here, from the viewpoint of semiconductor characteristics, “high-resistance” refers to such resistivity that causes the formation of a conductivity type inversion layer, by applying a voltage from the exterior, carrying out heat treatment, and so on, in a surface of the semiconductor where the voltage has been applied; as an example of a specific numeric value, the resistivity of several tens of Ωcm or more can be cited; as a typical value, the value in a range from no less than 100 Ωcm to approximately several kΩcm can be cited. The base member 20 is formed of, for example, a silicon substrate, which is a p-type semiconductor with small doping amounts.

In an interior portion of the base member 20 on the first principal surface side, the diode section 30 and the high concentration region 40 are formed as shown in FIGS. 1(A) and 1(B). The diode section 30 includes a first polar portion 31, a second polar portion 32, and a third polar portion 33.

The first polar portion 31 is formed having a predetermined depth on the first principal surface side of the base member 20. The first polar portion 31 is formed to be a reversed conductivity type with respect to the base member 20. For example, in the case where the base member 20 is a p-type, the first polar portion 31 is an n-type.

The second polar portion 32 and the third polar portion 33 are formed inside the first polar portion 31. The second polar portion 32 and the third polar portion 33 are exposed on the first principal surface of the base member 20. The second polar portion 32 and the third polar portion 33 are arranged adjacent to each other along the first direction in a plan view of the base member 20. The second polar portion 32 and the third polar portion 33 are formed to be different conductivity types from each other. For example, in the case where the second polar portion 32 is a p-type, the third polar portion 33 is an n-type.

In the above configuration, there is provided a pn junction between the second polar portion 32 and the third polar portion 33. As such, with the configurations mentioned above, the diode section 30 functions as a Zener diode.

As shown in FIG. 1(B), the high concentration region 40 is formed in a ring shape embracing the diode section 30 when the base member 20 is viewed in a direction orthogonal to the first principal surface, that is, in a plan view of the base member 20. The high concentration region 40 is formed to be the same conductivity type as the base member 20, but has a different content of impurities therefrom. For example, in the case where the base member 20 is a p-type, the high concentration region 40 is also a p-type, while the content of impurities configuring the p-type semiconductor is larger in the high concentration region 40 than in the base member 20. For example, the carrier concentration in the high concentration region 40 is approximately 1×10¹⁷ cm⁻³. Meanwhile, it is preferable for a depth of the high concentration region 40 to be 0.5 μm or more. The high concentration region 40 has a width being set based on the resistivity of the base member 20, and it is advisable for the width thereof, which is determined in accordance with the resistivity, to be no less than 5 μm if the resistivity is 100 Ωcm.

The insulation layer 21 is formed on the first principal surface of the base member 20. The insulation layer 21 is formed so as to cover substantially the entirety of the first principal surface of the base member 20, and has a shape exposing at least part of the second polar portion 32 and the third polar portion 33. The insulation layer 21 is formed of a highly insulative material such as SiO₂, for example.

The external connecting lands 22 and 23 are formed on the first principal surface of the base member 20 covered with the insulation layer 21. The external connecting lands 22 and 23 are rectangular conductor lands in plan view. The external connecting lands 22 and 23 are arranged along the first direction of the base member 20 with a space therebetween. The external connecting land 22 is connected to the second polar portion 32 via a through-hole formed in the insulation layer 21. The external connecting land 23 is connected to the third polar portion 33 via a through-hole formed in the insulation layer.

The protection layer 24 is formed, as shown in FIGS. 1(A) and 1(C), on the first principal surface of the base member 20 on which the external connecting lands 22 and 23 have been formed. The protection layer 24 is formed so as to cover substantially the entirety of the first principal surface, and has a shape where an area corresponding to a central portion of the external connecting lands 22 and 23 is opened. The protection layer 24 is formed of an insulative film or the like.

Having the configuration discussed above, the electrostatic protection device 10 is configured such that a Zener diode is connected between the external connecting lands 22 and 23, as shown in FIG. 1(D).

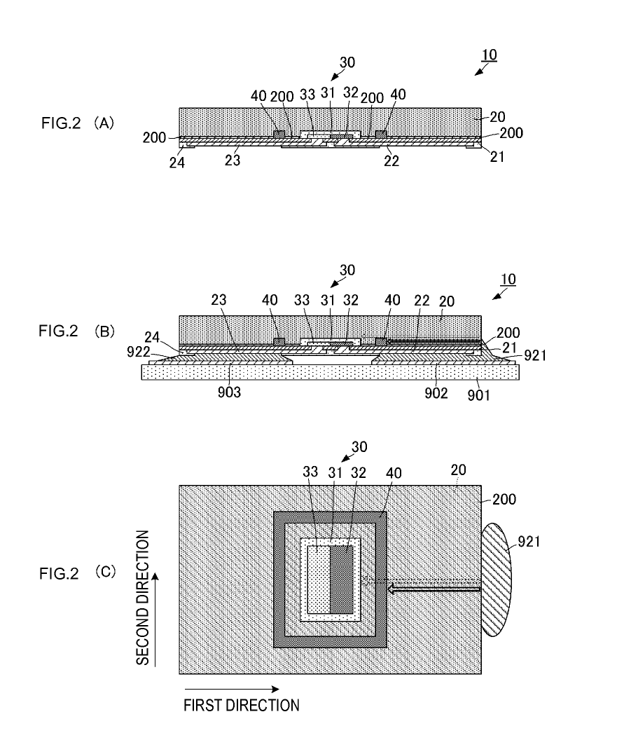

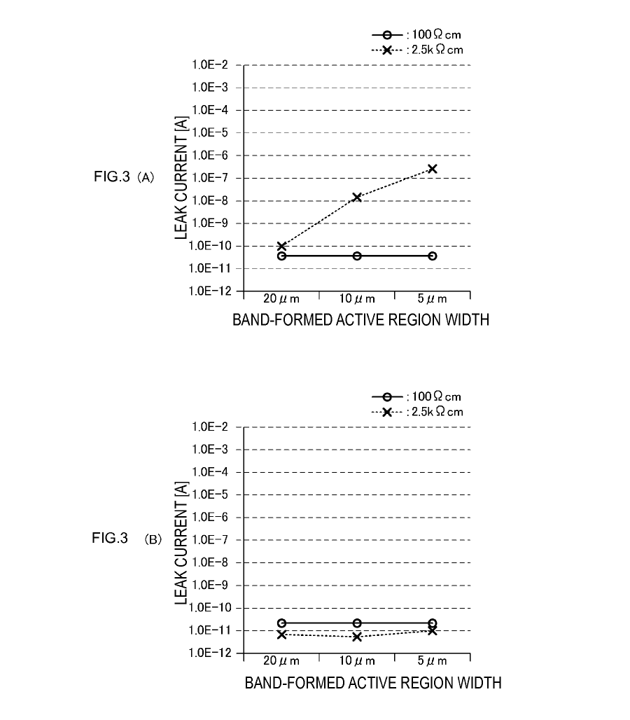

In the electrostatic protection device 10 configured as described above, the following effects can be achieved. FIGS. 2(A)-2(C) include drawings for explaining the effects of the electrostatic protection device according to the first embodiment of the present disclosure. FIG. 2(A) is a cross-sectional side view of the electrostatic protection device 10. FIG. 2(B) is a cross-sectional side view illustrating a state in which the electrostatic protection device 10 is mounted on a substrate 901. FIG. 2(C) is a bottom plan view of the base member 20 of the electrostatic protection device 10.

The base member 20 has high resistivity. To rephrase, impurities in small amounts are doped into the base member 20, and the high resistivity is realized while carrying out compensation control on impurity concentrations of both polarities. Therefore, in the case where heat treatment is applied in the semiconductor forming process in which impurities are doped from the first principal surface side in order to form the diode section 30, balance of the impurity compensation is likely to be lost substantially across the entirety of the first principal surface. This causes a conductivity type inversion layer 200 to be formed in a surface layer of the first principal surface of the base member 20, as shown in FIGS. 2(A) and 2(B).

Here, as shown in FIG. 2(B), the electrostatic protection device 10 is mounted on the substrate 901. The electrostatic protection device 10 is arranged with its first principal surface opposing the substrate 901. The external connecting land 22 of the electrostatic protection device 10 opposes a land pattern 902 of the substrate 901, and is connected to the land pattern 902 using solder 921. The external connecting land 23 of the electrostatic protection device 10 opposes a land pattern 903 of the substrate 901, and is connected to the land pattern 903 using solder 922.

At this time, as shown in FIG. 2(B), it is assumed that the solder 921 is attached to one end surface of the base member 20 in the first direction due to excessive solder supply. In this case, a current supplied through the land pattern 902 flows into the conductivity type inversion layer 200 through the solder 921.

Here, in a configuration where the high concentration region 40 of the electrostatic protection device 10 of the present embodiment is not present, in other words, in a conventional configuration, the current flows in the conductivity type inversion layer 200 and reaches the diode section 30, whereby a leak current that flows from the land pattern 902 to the third polar portion 33 of the diode section 30, as indicated by a dotted wide arrow in FIGS. 2(B) and 2(C), is generated.

However, like the electrostatic protection device 10 in the present embodiment, in the case where the high concentration region 40 is formed so as to enclose the diode section 30, the conductivity type inversion layer 200 is not formed in the high concentration region 40 because the high concentration region 40 is a region where large amounts of impurities have been doped. As such, an electron barrier is formed at a boundary between an inner side area of the high concentration region 40 (area including the diode section 30) and the high concentration region 40, and an electron barrier is also formed at a boundary between an outer side area of the high concentration region 40 (area on the end surface side of the base member 20) and the high concentration region 40, in a plan view of the first principal surface. In other words, the conductivity type inversion layer 200 in the inner side area of the high concentration region 40 and the conductivity type inversion layer 200 in the outer side area of the high concentration region 40 are isolated from each other by the electron barriers.

With this, as indicated by a bold wide arrow in FIGS. 2(B) and 2(C), the current that flows, through the solder 921, into the conductivity type inversion layer 200 located in the outer side area of the high concentration region 40 is blocked by the electron barriers, so that the stated current will not flow into the conductivity type inversion layer 200 located in the inner side area of the high concentration region 40. This makes it possible to suppress the generation of a leak current.

FIGS. 3(A) and 3(B) illustrate experiment results for explaining leak current suppression effects of the electrostatic protection device according to the first embodiment of the present disclosure. FIG. 3(A) indicates leak currents in the case where solder is attached to an end surface of the base member, as shown in FIGS. 2(B) and 2(C). Meanwhile, FIG. 3(B) indicates leak currents in the case where solder is not attached to an end surface of the base member 20. The horizontal axis represents the width of the high concentration region (band-formed high concentration region) and the vertical axis represents the magnitude of leak currents.

As shown in FIG. 3(B), in the case where the solder is not attached to the end surface of the base member 20, the magnitude of leak currents is approximately 1.0×10⁻¹¹ to 1.0×10⁻¹⁰ [A] regardless of resistivity of the base member 20 and a state of the high concentration region (width or the like).

On the other hand, as shown in FIG. 3(A), in the case where the solder is attached to the end surface of the base member 20, when the resistivity of the base member 20 is 100 Ωcm and the width of the high concentration region 40 is no less than 5 μm, the magnitude of leak currents is approximately 1.0×10⁻¹¹ to 1.0×10⁻¹⁰ [A]. In other words, the leak currents can be suppressed to a level of the magnitude when the solder is not being attached to the end surface of the base member 20.

Further, as shown in FIG. 3(A), in the case where the solder is attached to the end surface of the base member 20, when the resistivity of the base member 20 is 2.5 kΩcm and the width of the high concentration region 40 is no less than 20 μm, the magnitude of leak currents is approximately 1.0×10⁻¹¹ to 1.0×10⁻¹⁰ A. In other words, the leak currents can be suppressed to a level of the magnitude when the solder is not being attached to the end surface of the base member 20.

As discussed thus far, the generation of a leak current can be suppressed if the high concentration region 40 is formed in the manner as shown in the electrostatic protection device 10 of the present embodiment. Further, the generation of a leak current can be suppressed with certainty by appropriately setting the width of the high concentration region 40 in accordance with the resistivity of the base member 20. To be more specific, the generation of a leak current can be suppressed with certainty by widening the width of the high concentration region 40 as the resistivity of the base member 20 is larger.

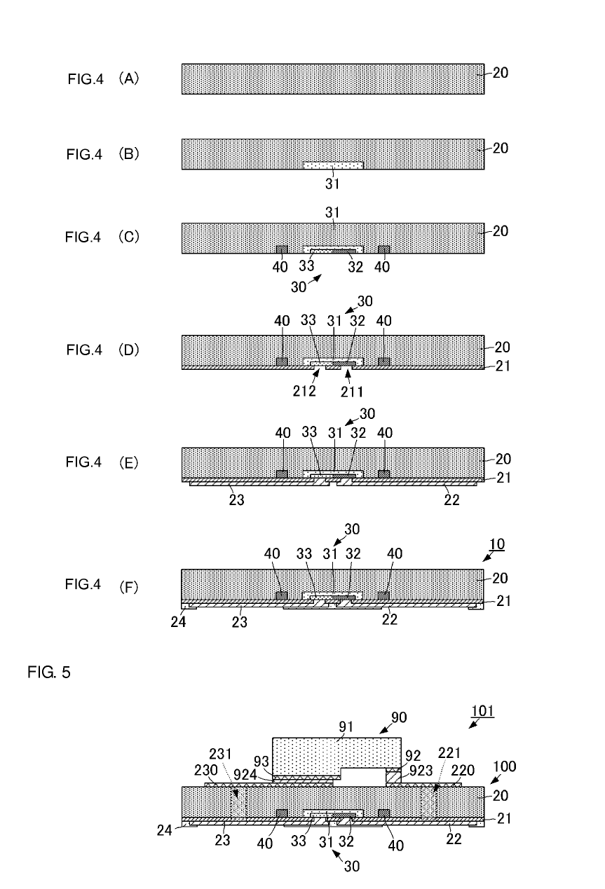

The electrostatic protection device 10 configured as discussed above can be formed through a manufacturing process described hereinafter. FIGS. 4(A)-4(F) include drawings illustrating a manufacturing process of the electrostatic protection device according to the first embodiment of the present disclosure. Each of FIGS. 4(A) through 4(F) is a cross-sectional side shape at each stage in the manufacturing process.

First, as shown in FIG. 4(A), the base member 20 formed of a high-resistance semiconductor is prepared. For example, a p-type silicon single crystal substrate whose resistivity is no less than 100 Ωcm is prepared as the base member 20.

Next, n-type impurities (carriers) are injected from the first principal surface side of the base member 20. With this, as shown in FIG. 4(B), the first polar portion 31 is formed in the base member 20 on the first principal surface side.

Next, p-type impurities (carriers) are injected from the first principal surface side of the base member 20 in a carrier concentration of 1.0×10¹⁷ cm⁻³ to form the second polar portion 32 inside the first polar portion 31 and form the high concentration region 40 so as to enclose the first polar portion 31, as shown in FIG. 4(C). Subsequently, n-type impurities (carriers) are injected from the first principal surface side of the base member 20 in a carrier concentration of 1.0×10¹⁷ cm⁻³ to form the third polar portion 33 inside the first polar portion 31 as shown in FIG. 4(C). Through this, the diode section 30 is formed in the base member 20 on the first principal surface side. The diode section 30 is enclosed by the high concentration region 40 formed in a ring shape.

Next, as shown in FIG. 4(D), the insulation layer 21 of SiO₂ is formed on the first principal surface of the base member 20. At this time, in the insulation layer 21, as shown in FIG. 4(D), a through-hole 211 through which a central area of the second polar portion 32 is opened to the exterior and a through-hole 212 through which a central area of the third polar portion 33 is opened to the exterior are formed.

Next, as shown in FIG. 4(E), the external connecting lands 22 and 23 are formed on a surface of the insulation layer 21 on the opposite side to the base member 20 using electrode patterns or the like. At this time, the external connecting land 22 is formed in a shape filling the through-hole 211 and connected to the second polar portion 32, as shown in FIG. 4(E). Also as shown in FIG. 4(E), the external connecting land 23 is formed to fill the through-hole 212 and connected to the third polar portion 33.

Next, as shown in FIG. 4(F), the protection layer 24 is formed using an insulative film or the like on the surface of the insulation layer 21, where the external connecting lands 22 and 23 have been formed, on the opposite side to the base member 20. At this time, the protection layer 24 is formed in a shape opening a central area of the external connecting lands 22 and 23, as shown in FIG. 4(F).

Using the above-described manufacturing process makes it possible to form the electrostatic protection device 10 discussed above. Further, in the electrostatic protection device 10 of the present embodiment, since the second polar portion 32 and the high concentration region 40 are the same conductivity type, the second polar portion 32 and the high concentration region 40 can be formed, as shown in FIG. 4(C), in one processing stage. This makes it possible to form the electrostatic protection device in a simpler manufacturing flow.

The above-discussed electrostatic protection device 10 can be used in a light-emitting module described hereinafter. FIG. 5 is a cross-sectional side view illustrating a configuration of a light-emitting module according to the first embodiment of the present disclosure.

A light-emitting module 101 includes an electrostatic protection device 100 and a light-emitting device 90. The light-emitting device 90 is, for example, an LED (light-emitting diode) device. The light-emitting device 90 includes a main body 91 that emits light when supplied with a current, and external terminals 92 and 93. The structure of the light-emitting device 90 is such that the external terminals 92 and 93 are arranged on a mount surface of the main body 91 while other constituent elements thereof are well-known. As such, descriptions of the other constituent elements are omitted herein. The light-emitting device 90 emits light being driven by a current supplied thereto through the external terminals 92 and 93.

The electrostatic protection device 100 has a configuration in which mounting lands 220, 230 and via conductors 221, 231 are added to the electrostatic protection device 10 discussed before.

The mounting lands 220 and 230 are formed on a second principal surface of the base member 20, or a surface on the opposite side to the first principal surface of the base member 20. The mounting land 220 is arranged so that at least part thereof opposes the external connecting land 22. The mounting land 230 is arranged so that at least part thereof opposes the external connecting land 23.

The external connecting land 22 and the mounting land 220 are connected to each other by the via conductor 221 penetrating the base member 20 in a thickness direction (a direction orthogonal to both the first direction and a second direction). The external connecting land 23 and the mounting land 230 are connected to each other by the via conductor 231 penetrating the base member 20 in the thickness direction.

The configuration described above makes it possible for the electrostatic protection device 100 to mount an electronic component on the second principal surface. Then, by mounting the electrostatic protection device 100, on which the above electronic component is mounted, on another substrate (not shown), a current and a voltage can be supplied from the external substrate to the electronic component.

Therefore, the light-emitting device 90 is mounted on this electrostatic protection device 100. The external terminal 92 of the light-emitting device 90 is connected to the mounting land 220 with solder 923 interposed therebetween. The external terminal 93 of the light-emitting device 90 is connected to the mounting land 230 with solder 924 interposed therebetween.

In the light-emitting module 101 configured as described above, in the case where the light-emitting device 90 is an LED, the light-emitting device 90 emits light when a current is flowed so as to bias the light-emitting device 90 in a forward direction. In the case where a large bias is applied to the light-emitting module 101, a current flows through the diode section 30 so as to prevent an overcurrent from flowing in the light-emitting device 90. With this, the light-emitting 90 can be prevented from being damaged.

Furthermore, by adopting the configuration of the present embodiment, a leak current is hardly generated even if solder or the like is attached to the end surface of the base member 20 in the electrostatic protection device 100, whereby the current can be stably supplied to the light-emitting device 90. Accordingly, a problem of decrease in brightness or the like can be prevented from arising.

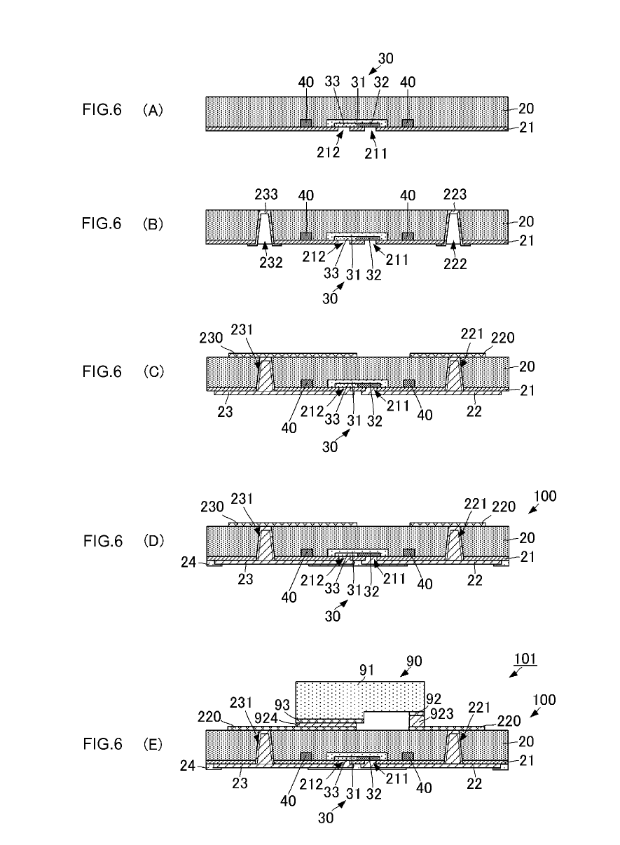

The light-emitting module 101 configured as discussed above can be formed through a manufacturing process described hereinafter. FIGS. 6(A)-6(E) include drawings illustrating a manufacturing process of the light-emitting module according to the first embodiment of the present disclosure. Each of FIGS. 6(A) through 6(E) is a cross-sectional side shape at each stage in the manufacturing process.

In this manufacturing process, the processing from the start to a stage in which the insulation layer 21 is formed in the electrostatic protection device 100 of the light-emitting module 101 is the same as the corresponding processing in the aforementioned manufacturing process of the electrostatic protection device 10, and therefore description thereof is omitted herein.

By adopting the above-mentioned manufacturing method, as shown in FIG. 6(A), a structure where the diode section 30 and the high concentration region 40 are formed in the base member 20 and the insulation layer 21 is further formed on the base member 20 is given.

Next, as shown in FIG. 6(B), through-holes 222 and 232 are formed penetrating the base member 20 in the thickness direction. The through-hole 222 is formed in a region where a formation region of the external connecting land 22 and a formation region of the mounting land 220 overlap in a plan view of the base member 20. The through-hole 232 is formed in a region where a formation region of the external connecting land 23 and a formation region of the mounting land 230 overlap in a plan view of the base member 20. A conductor pattern 223 is formed on a wall surface of the through-hole 222, and a conductor pattern 233 is formed on a wall surface of the through-hole 232.

Next, as shown in FIG. 6(C), filling the through-hole 222 with a conductor forms a via conductor 221, and filling the through-hole 232 with a conductor forms a via conductor 231. In addition, the external connecting lands 22 and 23 are formed on the first principal surface of the base member 20, and the mounting lands 220 and 230 are formed on the second principal surface of the base member 20.

Next, as shown in FIG. 6(D), the protection layer 24 is formed on the first principal surface side of the base member 20.

Next, as shown in FIG. 6(E), the light-emitting device 90 is mounted on the second principal surface side of the base member 20. In the light-emitting device 90, the external terminal 92 is connected to the mounting land 220 with the solder 923 interposed therebetween, and the external terminal 93 is connected to the mounting land 230 with the solder 924 interposed therebetween.

The light-emitting module 101 is formed through the above-described manufacturing process.

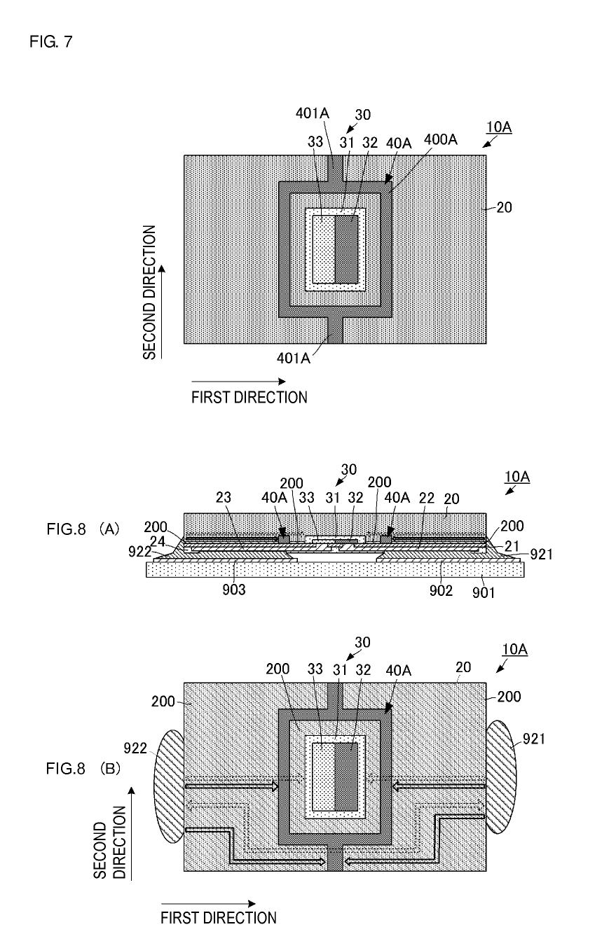

Next, an electrostatic protection device according to a second embodiment of the present disclosure will be described with reference to the drawings. FIG. 7 is a configuration diagram of an electrostatic protection device according to the second embodiment of the present disclosure. FIG. 7 is also a plan view of a base member on a first principal surface side thereof.

An electrostatic protection device 10A of the present embodiment differs from the electrostatic protection device 10 discussed in the first embodiment in that the shape of a high concentration region 40A is different from the shape of the high concentration region in the first embodiment, while other constituent elements are the same as those of the electrostatic protection device 10 discussed in the first embodiment. As such, only the different points will be described herein.

The high concentration region 40A of the electrostatic protection device 10A includes a ring-shaped portion 400A and a first extension portion 401A. The shape of the ring-shaped portion 400A is the same as that of the high concentration region 40 discussed in the first embodiment. There are two first extension portions 401A. The first extension portions 401A are formed in a shape such that each one end of the first extension portions 401A is connected to the ring-shaped portion 400A while the respective other ends thereof reach both end surfaces of the base member 20 in the second direction (direction orthogonal to the first direction) in a plan view of the base member 20.

With this, the conductivity type inversion layer is divided into an inner side area of the ring-shaped portion 400A, a one end surface side area at the outside of the ring-shaped portion 400A in the first direction of the base member 20, and the other end surface side area at the outside of the ring-shaped portion 400A in the first direction of the base member 20.

The following effects can be achieved by adopting the electrostatic protection device 10A configured as described above. FIGS. 8(A) and 8(B) include drawings for explaining the effects of the electrostatic protection device according to the second embodiment of the present disclosure. FIG. 8(A) is a cross-sectional side view illustrating a state in which the electrostatic protection device 10A is mounted on the substrate 901. FIG. 8(B) is a bottom plan view of the base member 20 of the electrostatic protection device 10A.

As shown in FIG. 8(A), the electrostatic protection device 10A is mounted on the substrate 901. At this time, as shown in FIG. 8(A), it is assumed that, due to excessive solder supply, the solder 921 is attached to the one end surface of the base member 20 in the first direction and the solder 922 is attached to the other end surface of the base member 20 in the first direction. In this case, a current supplied through the land pattern 902 flows into the conductivity type inversion layer 200 through the solder 921. Alternatively, a current supplied through the land pattern 903 flows into the conductivity type inversion layer 200 through the solder 922.

Here, in a configuration where the high concentration region 40A of the electrostatic protection device 10A of the present embodiment is not present, in other words, in a conventional configuration, the current flows in the conductivity type inversion layer 200 and reaches the diode section 30. As such, as indicated by dotted wide arrows in FIG. 8(B), a leak current that flows from the land pattern 902 to the third polar portion 33 of the diode section 30 is generated; further, a leak current that flows from the land pattern 903 to the second polar portion 32 of the diode section 30 is generated; and furthermore, a current flows in the conductivity type inversion layer 200 so that a leak current flows directly between the solder 921 and the solder 922.

However, like the electrostatic protection device 10A in the present embodiment, in the case where the high concentration region 40A is formed, as indicated by bold wide arrows in FIG. 8(B), a current that flows, through the solder 921 or 922, into the conductivity type inversion layer 200 located in the outer side area of the high concentration region 40A is blocked by the electron barriers, so that the current will not flow into the conductivity type inversion layer 200 located in the inner side area of the high concentration region 40A. In addition, electron barriers are also formed between the solder 921 and the solder 922 with the high concentration region 40A so that a leak current will not flow between the solder 921 and solder 922.

As discussed thus far, by adopting the configuration of the present embodiment, the generation of a leak current can be suppressed with certainty even if the solder 921 for mounting of the external connecting land 22 is attached to the one end surface of the base member 20 and the solder 922 for mounting of the external connecting land 23 is attached to the other end surface of the base member 20.

Next, an electrostatic protection device according to a third embodiment of the present disclosure will be described with reference to the drawings. FIG. 9 is a configuration diagram of an electrostatic protection device according to the third embodiment of the present disclosure. FIG. 9 is also a plan view of a base member on a first principal surface side thereof.

An electrostatic protection member 10B of the present embodiment differs from the electrostatic protection device 10 discussed in the first embodiment in that the shape of a high concentration region 40B is different from the shape of the high concentration region in the first embodiment, while other constituent elements are the same as those of the electrostatic protection device 10 discussed in the first embodiment. As such, only the different points will be described herein.

The high concentration region 40B of the electrostatic protection device 10B includes a ring-shaped portion 400B and a second extension portion 401B. The shape of the ring-shaped portion 400B is the same as that of the high concentration region 40 discussed in the first embodiment. There are four second extension portions 401B. The second extension portions 401B are formed in a shape such that each one end of the second extension portions 401B is connected to the ring-shaped portion 400B while the respective other ends thereof reach the corners of the base member 20 in a plan view of the base member 20.

With this, the conductivity type inversion layer is divided into an inner side area of the ring-shaped portion 400B, a one end surface side area at the outside of the ring-shaped portion 400B in the first direction of the base member 20, the other end surface side area at the outside of the ring-shaped portion 400B in the first direction of the base member 20, a one end surface side area at the outside of the ring-shaped portion 400B in the second direction of the base member 20, and the other end surface side area at the outside of the ring-shaped portion 400B in the second direction of the base member 20.

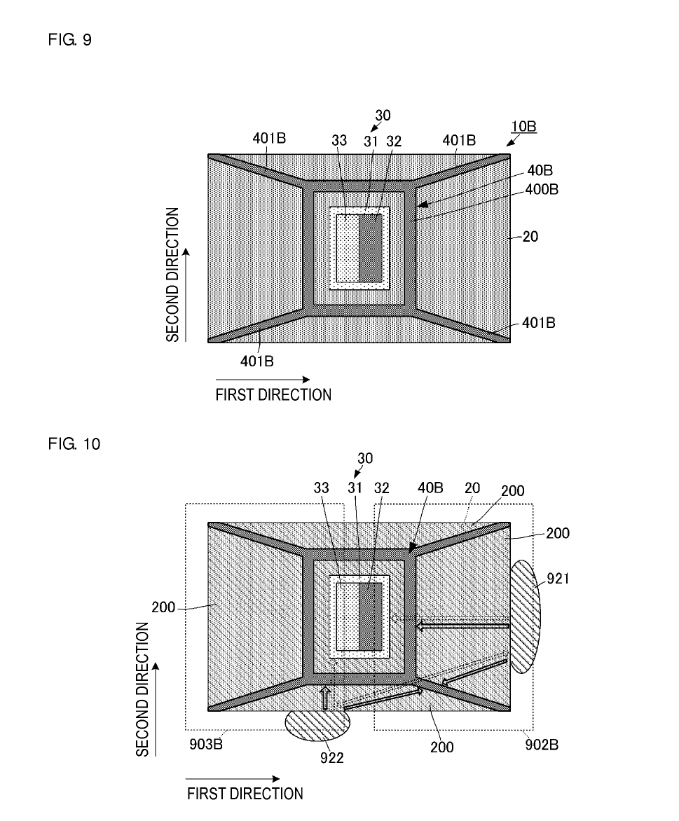

The following effects can be achieved by adopting the electrostatic protection device 10B configured as discussed above. FIG. 10 is a diagram for explaining the effects of the electrostatic protection device according to the third embodiment of the present disclosure. FIG. 10 is also a bottom plan view of the base member 20 of the electrostatic protection device 10B.

The length along the second direction of land patterns 902B and 903B of a substrate shown in FIG. 10 is longer than the length of the electrostatic protection member 10B in the second direction. The reason for this is as follows: that is, in the case where the electrostatic protection device 10B is mounted on a circuit board (not shown), it is easy for the external connecting lands 22 and 23 to be mounted on the land patterns 902B and 903B, respectively, even if the mounting position is shifted.

In this case, it can be thought of that the solder 922 for mounting the external connecting land 23 is attached to the one end surface in the second direction.

Here, in a configuration where the high concentration region 40B of the electrostatic protection device 10B of the present embodiment is not present, in other words, in a conventional configuration, the current flows in the conductivity type inversion layer 200 and reaches the diode section 30. Because of this, as indicated by dotted wide arrows in FIG. 10, a leak current that flows from the land pattern 902B to the third polar portion 33 of the diode section 30 is generated; further, a leak current that flows from the land pattern 903B to the second polar portion 32 of the diode section 30 is generated; and furthermore, a current flows in the conductivity type inversion layer 200 so that a leak current flows directly between the solder 921 and the solder 922.

However, like the electrostatic protection device 10B in the present embodiment, in the case where the high concentration region 40B is formed, as indicated by bold wide arrows in FIG. 10, a current that flows, through the solder 921 or 922, into the conductivity type inversion layer 200 located in the outer side area of the high concentration region 40B is blocked by the electron barriers, so that the current will not flow into the conductivity type inversion layer 200 located in the inner side area of the high concentration region 40B. In addition, electron barriers are also formed between the solder 921 and the solder 922 with the high concentration region 40B so that a leak current will not flow between the solder 921 and solder 922. In particular, in the configuration of the present embodiment, a leak current will not flow between the solder 921 attached to the end surface in the first direction and the solder 922 attached to the end surface in the second direction.

As discussed thus far, by adopting the configuration of the present embodiment, the generation of a leak current can be suppressed with certainty even if the solder 921 for mounting the external connecting land 22 is attached to the one end surface of the base member 20 in the first direction and the solder 922 for mounting the external connecting land 23 is attached to the one end surface of the base member 20 in the second direction.

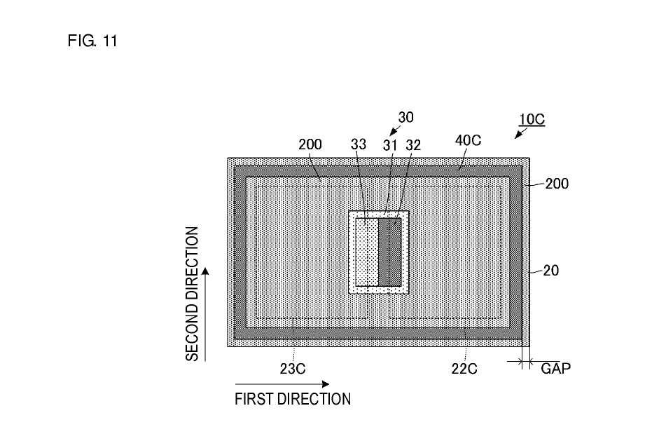

Next, an electrostatic protection device according to a fourth embodiment of the present disclosure will be described with reference to the drawings. FIG. 11 is a configuration diagram of an electrostatic protection device according to the fourth embodiment of the present disclosure. FIG. 11 is also a plan view of a base member on a first principal surface side.

An electrostatic protection device 10C of the present embodiment differs from the electrostatic protection device 10 discussed in the first embodiment in that the shape of a high concentration region 40C is different from the shape of the high concentration region in the first embodiment, while other constituent elements are the same as those of the electrostatic protection device 10 discussed in the first embodiment. As such, only the different points will be described herein.

Like the high concentration region 40 discussed in the first embodiment, the high concentration region 40C is formed in a ring shape. In a plan view of the base member 20, the high concentration region 40C is formed in the shape enclosing not only the diode section 30 but also external connecting lands 22C and 23C. In this case, the high concentration region 40C is arranged being distanced from each end side of the base member 20 by a gap of GAP in a plan view of the base member 20.

The following effects can be achieved by adopting the above-described configuration. That is, since the high concentration region 40C contains large amounts of impurities, a conductivity type inversion layer is generally not formed. However, there is a possibility of generation of a conductivity type inversion layer in the case where a voltage is applied through the external connecting lands 22C and 23C.

Here, the high concentration region 40C described in the present embodiment is arranged at a position where it does not overlap with the external connecting lands 22C or 23C in a plan view of the base member 20. Accordingly, even if a voltage is applied to the external connecting lands 22C or 23C, a conductivity type inversion layer will not be formed in the high concentration region 40C. This makes it possible to suppress the generation of a leak current with certainty.

Moreover, since the high concentration region 40C of the present embodiment is distanced from the end side of the base member 20, the solder will not be directly attached to the high concentration region 40C. As such, the generation of a leak current that flows through the high concentration region 40C can be prevented as well.

Note that the configurations discussed in the above embodiments are typical examples, and such configurations can be appropriately combined and used. For example, the configuration of the ring-shaped portion 400A and the first extension portions 401A discussed in the second embodiment and the configuration of the second extension portions 401B discussed in the third embodiment may be combined together. In addition, the high concentration region 40 discussed in the first embodiment and the high concentration region 40C discussed in the fourth embodiment may be combined together. In other words, the ring-shaped high concentration regions may be provided in a superimposed manner.

Although a case in which the electrostatic protection device 10 having the configuration of the first embodiment is used in the light-emitting module is given in the above description, another electrostatic protection device having the configuration according to any one of the other embodiments may be used to configure the light-emitting module in a mounting mode similar to that of the first embodiment.

1. An electrostatic protection device comprising:
a base member formed of a semiconductor material; and
a diode section formed on a first principal surface side of the base member through a semiconductor forming process,
wherein the base member has such resistivity that causes formation of a conductivity type inversion layer in the base member by applying a voltage from an exterior, carrying out heat treatment, and
the base member includes a high concentration region formed in a shape extending from the first principal surface to an interior of the base member so as to enclose the diode section in a plan view of the base member when seen from the first principal surface side, is of a same conductivity type as the base member, and has a higher impurity concentration than the base member.

2. The electrostatic protection device according to claim 1,
wherein the high concentration region includes;
an enclosure portion enclosing the diode section, and
at least one of a first extension portion that is formed in a shape connected to the enclosure portion and extending to both ends of the first principal surface opposing each other and a second extension portion connected to the enclosure portion and extending to respective corners of the first principal surface.

3. The electrostatic protection device according to claim 1,
further comprising a first external connecting land and a second external connecting land formed on the first principal surface of the base member with a predetermined space between the first and second external connecting lands along a first direction of the first principal surface, and
the diode section is formed between the first external connecting land and the second external connecting land on the first principal surface side of the base member.

4. The electrostatic protection device according to claim 1,
wherein the high concentration region is formed in a ring shape embracing the first external connecting land and the second external connecting land in a plan view of the first principal surface.

5. The electrostatic protection device according to claim 1,
wherein a width of the high concentration region is wider as resistivity of the base member is higher.

6. The electrostatic protection device according to claim 5, further comprising:
a first mounting land and a second mounting land formed on a second principal surface of the base member opposing the first principal surface,
a first via conductor that connects the first external connecting land and the first mounting land, and
a second via conductor that connects the second external connecting land and the second mounting land.

7. A light-emitting module comprising:
the electrostatic protection device according to claim 6; and
a light-emitting device in which a first external terminal is mounted on the first mounting land, and a second external terminal is mounted on the second mounting land.
